(19) United States
(12) Patent Application Publication
(10) Pub. No.: US 2023/0336140 A1
(43) Pub. Date: Oct. 19, 2023

(54) ACOUSTIC WAVE DEVICE

(71) Applicant: Murata Manufacturing Co., Ltd., Nagaokakyo-shi (JP)

(72) Inventor: Kazunori INOUE, Nagaokakyo-shi (JP)

(21) Appl. No.: 18/211,737

(22) Filed: Jun. 20, 2023

Related U.S. Application Data
(63) Continuation of application No. PCT/JP2021/047631, filed on Dec. 22, 2021.
(60) Provisional application No. 63/129,701, filed on Dec. 23, 2020.

(51) Int. Cl. H03H 9/02; H03H 9/13; H03H 9/17

(52) U.S. Cl. CPC H03H 9/02133; H03H 9/02031; H03H 9/02102; H03H 9/02228; H03H 9/13; H03H 9/173; H03H 9/174; H03H 9/176

(57) ABSTRACT

An acoustic wave device includes a support including a support substrate, a piezoelectric layer extending in a first direction, which is a thickness direction of the support substrate, an IDT electrode provided in the first direction of the piezoelectric layer and including first and second busbars facing each other, first electrode fingers each including a base end connected to the first busbar, and second electrode fingers each including a base end connected to the second busbar, and a reinforcing film provided in the first direction of the piezoelectric layer. The support includes a cavity open to the piezoelectric layer side in the first direction, and the reinforcing film overlaps at least a portion of a boundary between a region where the piezoelectric layer and the cavity overlap and a region where the piezoelectric layer and the cavity do not overlap in a plan view in the first direction.

### CROSS REFERENCE TO RELATED APPLICATIONS

This application claims the benefit of priority to Provisional Application No. 63/129,701 filed on Dec. 23, 2020 and is a Continuation Application of PCT Application No. PCT/JP2021/047631 filed on Dec. 22, 2021. The entire contents of each application are hereby incorporated herein by reference.

### BACKGROUND OF THE INVENTION

### 1. Field of the Invention

The present disclosure relates to an acoustic wave device.

### 2. Description of the Related Art

Japanese Unexamined Patent Application Publication No. 2012-257019 discloses an acoustic wave device.

### SUMMARY OF THE INVENTION

In Japanese Unexamined Patent Application Publication No. 2012-257019, when a cavity portion is provided in a support member, cracks may occur in a portion of a piezoelectric layer, which overlaps an outer wall of the cavity portion in a plan view in a thickness direction of the support member and in which no electrode is provided. Therefore, it is necessary to reduce or prevent the occurrence of the cracks in the piezoelectric layer around the cavity portion.

Preferred embodiments of the present invention reduce or prevent the occurrence of cracks in a piezoelectric layer.

An acoustic wave device according to an aspect of a preferred embodiment of the present invention includes a support including a support substrate, a piezoelectric layer that includes lithium niobate or lithium tantalate and is provided in a first direction, which is a thickness direction of the support substrate, an interdigital transducer (IDT) electrode provided in the first direction of the piezoelectric layer and including a first busbar and a second busbar that face each other, a plurality of first electrode fingers each including a base end connected to the first busbar, and a plurality of second electrode fingers each including a base end connected to the second busbar, and a reinforcing film provided in the first direction of the piezoelectric layer, in which the support includes a cavity portion that is open to the piezoelectric layer side in the first direction, and the reinforcing film overlaps at least a portion of a boundary between a region where the piezoelectric layer and the cavity portion overlap and a region where the piezoelectric layer and the cavity portion do not overlap in a plan view in the first direction.

According to preferred embodiments of the present disclosure, it is possible to reduce or prevent the occurrence of cracks in a piezoelectric layer.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a perspective view illustrating an acoustic wave device of a first preferred embodiment of the present invention.

FIG. 1B is a plan view illustrating the structure of electrodes of the first preferred embodiment of the present invention.

FIG. 2 is a cross-sectional view of a portion taken along a line II-II of FIG. 1A.

FIG. 3A is a schematic cross-sectional view for explaining Lamb waves propagating through a piezoelectric layer of a comparative example.

FIG. 3B is a schematic cross-sectional view for explaining bulk waves in a first-order thickness-shear mode propagating through a piezoelectric layer of the first preferred embodiment of the present invention.

FIG. 4 is a schematic cross-sectional view for explaining an amplitude direction of bulk waves in the first-order thickness-shear mode propagating through the piezoelectric layer of the first preferred embodiment of the present invention.

FIG. 5 is an explanatory diagram illustrating an example of resonance characteristics of the acoustic wave device of the first preferred embodiment of the present invention.

FIG. 6 is an explanatory diagram illustrating a relationship between d/2p and a fractional bandwidth as a resonator in the acoustic wave device of the first preferred embodiment of the present invention, when p is a center-to-center distance or an average distance of the center-to-center distances between adjacent electrodes to each other, and d is an average thickness of the piezoelectric layer.

FIG. 7 is a plan view illustrating an example in which a pair of electrodes are provided in the acoustic wave device of the first preferred embodiment of the present invention.

FIG. 8 is a reference diagram illustrating an example of resonance characteristics of the acoustic wave device of the first preferred embodiment of the present invention.

FIG. 9 is an explanatory diagram illustrating a relationship between the fractional bandwidth and the phase rotation amount of a spurious emission impedance normalized by 180 degrees as the magnitude of a spurious emission when a large number of acoustic wave resonators are included in the acoustic wave device of the first preferred embodiment of the present invention.

FIG. 10 is an explanatory diagram illustrating a relationship between d/2p, a metallization ratio MR, and a fractional bandwidth.

FIG. 11 is an explanatory diagram illustrating a map of the fractional bandwidth with respect to the Euler angles (0°, θ, ψ) of LiNbO₃ when d/p is made as close to 0 as possible.

FIG. 12 is a partially cutaway perspective view for explaining an acoustic wave device according to a preferred embodiment of the present invention.

FIG. 13 is a plan view illustrating a first example of the acoustic wave device according to the first preferred embodiment of the present invention.

FIG. 14 is a diagram illustrating an example of a cross section of a portion taken along a line A-A′ of FIG. 13.

FIG. 15 is a diagram illustrating an example of a cross section of a portion taken along a line B-B′ of FIG. 13.

FIG. 16 is a diagram illustrating a different example of a cross section of a portion taken along a line A-A′ of FIG. 13.

FIG. 17 is a plan view illustrating a second example of the acoustic wave device according to the first preferred embodiment of the present invention.

FIG. 18 is a plan view illustrating a third example of the acoustic wave device according to the first preferred embodiment of the present invention.

FIG. 19 is a plan view illustrating a fourth example of the acoustic wave device according to the first preferred embodiment of the present invention.

### DETAILED DESCRIPTION OF THE PREFERRED EMBODIMENTS

Hereinafter, preferred embodiments of the present disclosure will be described in detail with reference to the drawings. Note that the present disclosure is not limited to the preferred embodiments. Note that each preferred embodiment described in the present disclosure is an example, and in modifications in which partial replacement or combination of configurations is possible in different preferred embodiments, and a second preferred embodiment and subsequent preferred embodiments, description of matters common with a first preferred embodiment will be omitted and only different points will be described. In particular, similar functions and effects obtained by similar configurations will not be described in each preferred embodiment.

### First Preferred Embodiment

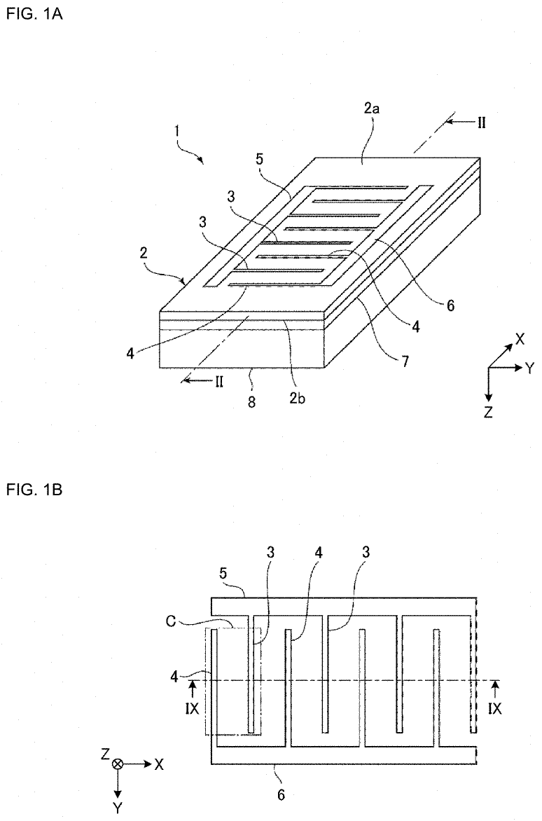

FIG. 1A is a perspective view illustrating an acoustic wave device of a first preferred embodiment. FIG. 1B is a plan view illustrating the structure of electrodes of the first preferred embodiment.

An acoustic wave device 1 of the first preferred embodiment includes a piezoelectric layer 2 made of LiNbO₃. The piezoelectric layer 2 may be made of LiTaO₃. The cut angle of LiNbO₃ or LiTaO₃ is a Z-cut in the first preferred embodiment. The cut angle of LiNbO₃ or LiTaO₃ may be a rotated Y-cut or X-cut. The propagation orientation of Y propagation and X propagation of about ±30° are preferable, for example.

The thickness of the piezoelectric layer 2 is not particularly limited but is preferably equal to or more than about 50 nm and equal to or less than about 1000 nm in order to effectively excite a first-order thickness-shear mode.

The piezoelectric layer 2 includes a first main surface 2a and a second main surface 2b facing each other in a Z direction. An electrode finger 3 and an electrode finger 4 are provided on the first main surface 2a.

Here, the electrode finger 3 is an example of a “first electrode finger”, and the electrode finger 4 is an example of a “second electrode finger”. In FIGS. 1A and 1B, the plurality of electrode fingers 3 is a plurality of “first electrodes” connected to a first busbar 5. The plurality of electrode fingers 4 is a plurality of “second electrodes” connected to a second busbar 6. The plurality of electrode fingers 3 and the plurality of electrode fingers 4 are interdigitated with each other. Thus, an interdigital transducer (IDT) electrode 30 including the plurality of electrode fingers 3, the plurality of electrode fingers 4, the first busbar 5, and the second busbar 6 is formed.

The electrode finger 3 and the electrode finger 4 have a rectangular or substantially rectangular shape and have a length direction. In a direction orthogonal to the length direction, the electrode finger 3 and the electrode finger 4 adjacent to the electrode finger 3 face each other. The length direction of the electrode finger 3 and the electrode finger 4 and the direction orthogonal to the length direction of the electrode finger 3 and the electrode finger 4 each are a direction intersecting the thickness direction of the piezoelectric layer 2. Therefore, it can also be said that the electrode finger 3 and the electrode finger 4 adjacent to the electrode finger 3 face each other in the direction intersecting the thickness direction of the piezoelectric layer 2. In the following description, the thickness direction of the piezoelectric layer 2 may be referred to as the Z direction (or a first direction), the length direction of the electrode finger 3 and the electrode finger 4 may be referred to as a Y direction (or a second direction), and the direction orthogonal to the length direction of the electrode finger 3 and the electrode finger 4 may be referred to as an X direction (or a third direction).

Further, the length direction of the electrode finger 3 and the electrode finger 4 may be replaced with the direction orthogonal to the length direction of the electrode finger 3 and the electrode finger 4 illustrated in FIGS. 1A and 1B. That is, the electrode finger 3 and the electrode finger 4 may be extended in a direction in which the first busbar 5 and the second busbar 6 extend in FIGS. 1A and 1B. In this case, the first busbar 5 and the second busbar 6 extend in a direction in which the electrode finger 3 and the electrode finger 4 extend in FIGS. 1A and 1B. A plurality of pairs of structures in which the electrode finger 3 connected to one potential and the electrode finger 4 connected to the other potential are adjacent to each other is provided in a direction orthogonal to the length direction of the above electrode fingers 3 and 4.

Here, the electrode finger 3 and the electrode finger 4 being adjacent to each other refers not to a case where the electrode finger 3 and the electrode finger 4 are arranged so as to be in direct contact with each other but to a case where the electrode finger 3 and the electrode finger 4 are arranged with an interval therebetween. In addition, when the electrode finger 3 and the electrode finger 4 are adjacent to each other, an electrode connected to a hot electrode or a ground electrode, including the other electrode fingers 3 and 4, is not arranged between the electrode finger 3 and the electrode finger 4. The number of pairs need not be integer pairs, but may be 1.5 pairs, 2.5 pairs, or the like.

A center-to-center distance between the electrode finger 3 and the electrode finger 4, that is, a pitch is preferably in the range of equal to or more than about 1 μm and equal to or less than about 10 μm, for example. In addition, the center-to-center distance between the electrode finger 3 and the electrode finger 4 is a distance connecting the center of the width dimension of the electrode finger 3 in the direction orthogonal to the length direction of the electrode finger 3 and the center of the width dimension of the electrode finger 4 in the direction orthogonal to the length direction of the electrode finger 4.

Further, in a case where the number of at least one of the electrode finger 3 and the electrode finger 4 is plural (when the electrode finger 3 and the electrode finger 4 make a pair of electrode set, there are 1.5 or more pairs of electrode sets), the center-to-center distance between the electrode finger 3 and the electrode finger 4 refers to the average value of the center-to-center distances between the respective adjacent electrode fingers 3 and 4 to each other of the 1.5 or more pairs of electrode fingers 3 and 4.

In addition, the width of the electrode fingers 3 and 4, that is, the dimension of the electrode fingers 3 and 4 in their facing direction, is preferably in the range of equal to or more than about 150 nm and equal to or less than about 1000 nm, for example. Note that the center-to-center distance between the electrode finger 3 and the electrode finger 4 is a distance connecting the center of the dimension (width dimension) of the electrode finger 3 in the direction orthogonal to the length direction of the electrode finger 3 and the center of the dimension (width dimension) of the electrode finger 4 in the direction orthogonal to the length direction of the electrode finger 4.

In addition, in the first preferred embodiment, since the Z-cut piezoelectric layer is used, the direction orthogonal to the length direction of the electrode fingers 3 and 4 is a direction orthogonal to the polarization direction of the piezoelectric layer 2. The above case does not apply when a piezoelectric body of another cut angle is used as the piezoelectric layer 2. Here, “orthogonal” is not limited to strictly orthogonal but may be substantially orthogonal (an angle formed by the direction orthogonal to the length direction of the electrode finger 3 and the electrode finger 4 and the polarization direction is, for example, about 90°±10°).

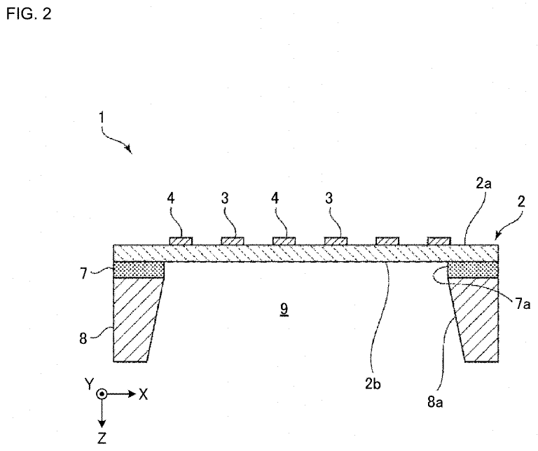

A support substrate 8 is laminated on the second main surface 2b side of the piezoelectric layer 2 via a dielectric film 7. The dielectric film 7 and the support substrate 8 have a frame shape and have opening portions 7a and 8a as illustrated in FIG. 2. Thus, a cavity portion (air gap) 9 is formed.

The cavity portion 9 is provided so as not to interfere with the vibration of an excitation region C of the piezoelectric layer 2. Therefore, the above support substrate 8 is laminated on the second main surface 2b via the dielectric film 7 at a position not overlapping a portion in which at least a pair of electrode fingers 3 and 4 are provided. Note that the dielectric film 7 need not be provided. Therefore, the support substrate 8 can be directly or indirectly laminated on the second main surface 2b of the piezoelectric layer 2.

The dielectric film 7 is formed of silicon oxide. However, the dielectric film 7 can be formed of an appropriate insulating material such as silicon nitride, alumina or the like in addition to silicon oxide.

The support substrate 8 is formed of Si. The plane orientation of the surface of Si on the piezoelectric layer 2 side may be (100), (110) or (111). Preferably, high-resistance Si having resistivity of equal to or more than 4 kΩ is desirable. However, the support substrate 8 can also be formed using an appropriate insulating material or semiconductor material. As for the material of the support substrate 8, piezoelectric bodies such as aluminum oxide, lithium tantalate, lithium niobate, crystal and the like; various ceramics such as alumina, magnesia, sapphire, silicon nitride, aluminum nitride, silicon carbide, zirconia, cordierite, mullite, steatite, forsterite and the like; dielectrics such as diamond, glass and the like; and semiconductors such as gallium nitride, and the like can be used.

The plurality of electrode fingers 3 and 4, the first busbar 5, and the second busbar 6 are made of an appropriate metal or alloy such as Al, an AlCu alloy or the like. In the first preferred embodiment, the electrode fingers 3 and 4, the first busbar 5, and the second busbar 6 have a structure in which an Al film is laminated on a Ti film. Note that a close contact layer other than the Ti film may be used.

At the time of driving, an AC voltage is applied between the plurality of electrode fingers 3 and the plurality of electrode fingers 4. More specifically, the AC voltage is applied between the first busbar 5 and the second busbar 6. As a result, it is possible to obtain resonance characteristics using bulk waves in the first-order thickness-shear mode excited in the piezoelectric layer 2.

In addition, in the acoustic wave device 1, when the thickness of the piezoelectric layer 2 is defined as d, and the center-to-center distance between any adjacent electrode fingers 3 and 4 to each other among the plurality of pairs of electrode fingers 3 and 4 is defined as p, d/p is set to be equal to or less than about 0.5, for example. Therefore, the bulk waves in the above first-order thickness-shear mode are effectively excited, and good resonance characteristics can be obtained. More preferably, d/p is equal to or less than about 0.24, for example, in which case even better resonance characteristics can be obtained.

Note that in a case where the number of at least one of the electrode finger 3 and the electrode finger 4 is plural as in the first preferred embodiment, that is, when the electrode finger 3 and the electrode finger 4 make a pair of electrode set, in a case where there are 1.5 or more pairs of the electrode finger 3 and the electrode finger 4, the center-to-center distance p between the adjacent electrode fingers 3 and 4 to each other is an average distance of the center-to-center distances between the respective adjacent electrode fingers 3 and 4 to each other.

Since the acoustic wave device 1 of the first preferred embodiment has the above-described configuration, even when the number of pairs of the electrode finger 3 and the electrode finger 4 is reduced in an attempt to achieve a reduction in size, Q value is not easily reduced. This is because the resonator does not require reflectors on both sides and has a small propagation loss. In addition, the reason why the above reflector is not required is that the bulk waves in the first-order thickness-shear mode are used.

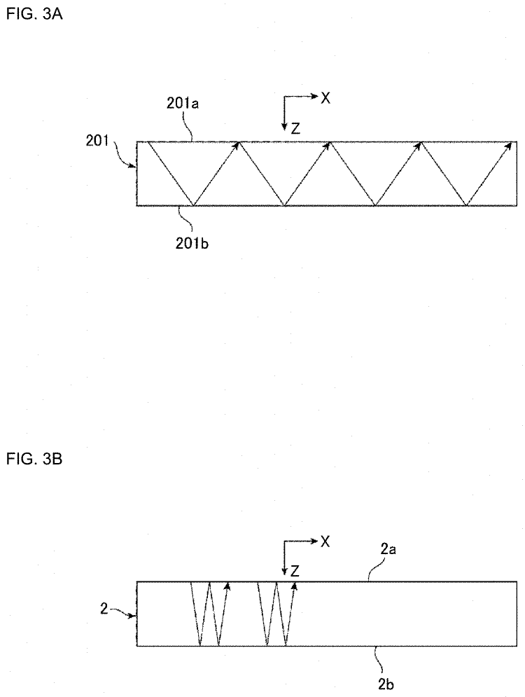

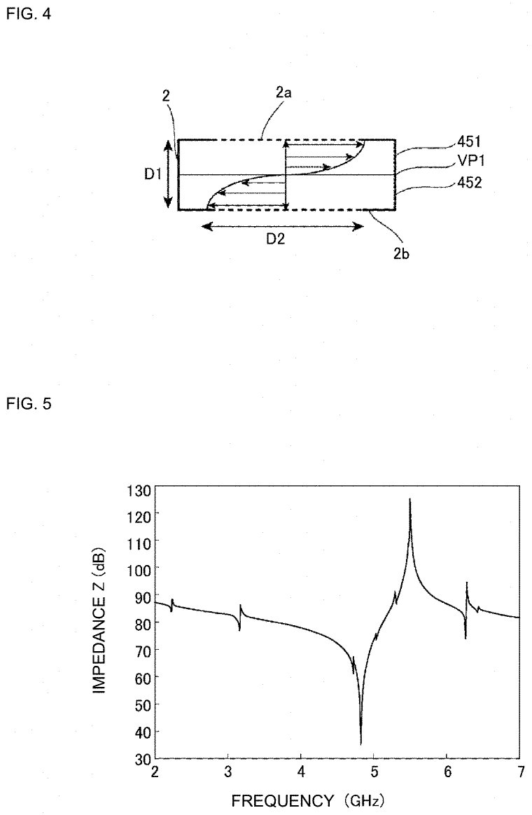

FIG. 3A is a schematic cross-sectional view for explaining Lamb waves propagating through a piezoelectric layer of a comparative example. FIG. 3B is a schematic cross-sectional view for explaining bulk waves in the first-order thickness-shear mode propagating through the piezoelectric layer of the first preferred embodiment. FIG. 4 is a schematic cross-sectional view for explaining an amplitude direction of the bulk waves in the first-order thickness-shear mode propagating through the piezoelectric layer of the first preferred embodiment.

In FIG. 3A, an acoustic wave device as described in Japanese Unexamined Patent Application Publication No. 2012-257019 is illustrated, and Lamb waves propagate through a piezoelectric layer. As illustrated in FIG. 3A, waves propagate through a piezoelectric layer 201 as indicated by arrows. Here, the piezoelectric layer 201 has a first main surface 201a and a second main surface 201b, and the thickness direction connecting the first main surface 201a and the second main surface 201b is the Z direction. The X direction is a direction in which the electrode fingers 3 and 4 of the IDT electrode 30 are arranged. As illustrated in FIG. 3A, the Lamb waves propagate in the X direction as illustrated in the figure. Although the piezoelectric layer 201 vibrates as a whole because of plate waves, since the waves propagate in the X direction, the reflectors are arranged on both sides to obtain resonance characteristics. Therefore, a propagation loss of waves occurs, and the Q value decreases when the size is reduced, that is, when the number of pairs of electrode fingers 3 and 4 is reduced.

On the other hand, as illustrated in FIG. 3B, in the acoustic wave device of the first preferred embodiment, since vibration displacement is in the thickness-shear direction, the wave substantially propagates in a direction connecting the first main surface 2a and the second main surface 2b of the piezoelectric layer 2, that is, the Z direction, and resonates. That is, the X direction component of the wave is significantly smaller than the Z direction component. Since the resonance characteristics are obtained by the propagation of the wave in the Z direction, a reflector is not required. Therefore, the propagation loss does not occur when the wave propagates to the reflector. Therefore, even when the number of pairs of electrodes consisting of the electrode finger 3 and the electrode finger 4 is reduced in an attempt to reduce the size, the Q value is not easily reduced.

Note that as illustrated in FIG. 4, the amplitude directions of the bulk waves in the first-order thickness-shear mode are opposite in a first region 451 included in the excitation region C (see FIG. 1B) of the piezoelectric layer 2 and a second region 452 included in the excitation region C. FIG. 4 schematically illustrates the bulk waves when a voltage is applied between the electrode finger 3 and the electrode finger 4 so that the electrode finger 4 has a higher potential than the electrode finger 3. The first region 451 is a region between the first main surface 2a and a virtual plane VP1 that is orthogonal to the thickness direction of the piezoelectric layer 2 and divides the piezoelectric layer 2 into two parts in the excitation region C. The second region 452 is a region between the virtual plane VP1 and the second main surface 2b in the excitation region C.

In the acoustic wave device 1, at least a pair of electrodes of the electrode finger 3 and the electrode finger 4 are arranged, however, since waves are not propagated in the X direction, the number of pairs of electrodes of the electrode finger 3 and the electrode finger 4 does not necessarily have to be plural. That is, only at least a pair of electrodes may be provided.

For example, the above electrode finger 3 is an electrode connected to a hot potential, and the electrode finger 4 is an electrode connected to a ground potential. However, the electrode finger 3 may be connected to the ground potential and the electrode finger 4 may be connected to the hot potential. In the first preferred embodiment, as described above, at least a pair of electrodes are an electrode connected to the hot potential or an electrode connected to the ground potential, and a floating electrode is not provided.

FIG. 5 is an explanatory diagram illustrating an example of resonance characteristics of the acoustic wave device of the first preferred embodiment. Note that the design parameters of an example of the acoustic wave device 1 having the resonance characteristics illustrated in FIG. 5 are as follows.
Piezoelectric layer 2: LiNbO₃ with Euler angles (0°, 0°, 90°)
Thickness of piezoelectric layer 2: 400 nm Length of excitation region C (see FIG. 1B): 40 μm
Number of pairs of electrodes of electrode finger 3 and electrode finger 4: 21 pairs
Center-to-center distance (pitch) between electrode finger 3 and electrode finger 4: 3 μm
Width of electrode fingers 3 and 4: 500 nm
d/p: 0.133
Dielectric film 7: silicon oxide film with thickness of 1 μm
Support substrate 8: Si

Note that the excitation region C (see FIG. 1B) is a region where the electrode finger 3 and the electrode finger 4 overlap when viewed in the X direction orthogonal to the length direction of the electrode fingers 3 and 4. The length of the excitation region C is a dimension of the excitation region C along the length direction of the electrode fingers 3 and 4. Here, the excitation region C is an example of an “intersection region”.

In the first preferred embodiment, the distances between respective electrodes of the electrode pairs of the electrode fingers 3 and the electrode fingers 4 were all equal in the plurality of pairs. That is, the electrode fingers 3 and the electrode fingers 4 were arranged with equal pitches.

As is apparent from FIG. 5, good resonance characteristics with a fractional bandwidth of about 12.5%, for example, are obtained even though no reflector is provided.

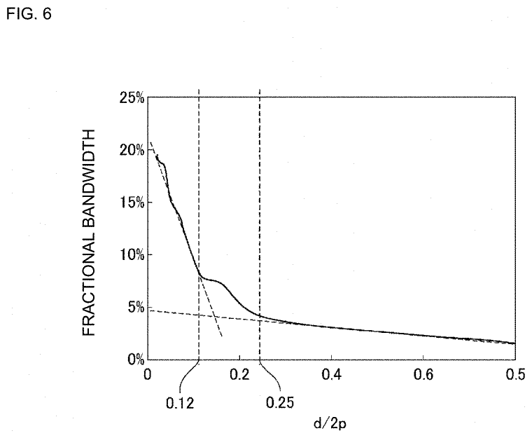

In the first preferred embodiment, when the thickness of the above piezoelectric layer 2 is defined as d and the center-to-center distance between the electrode finger 3 and the electrode finger 4 is defined as p, d/p is equal to or less than about 0.5, more preferably equal to or less than about 0.24, for example. The above relationship will be described with reference to FIG. 6.

A plurality of acoustic wave devices was obtained in the same manner as the acoustic wave device having the resonance characteristics illustrated in FIG. 5, except that d/2p was changed. FIG. 6 is an explanatory diagram illustrating a relationship between d/2p and the fractional bandwidth as the resonator in the acoustic wave device of the first preferred embodiment, when p is the center-to-center distance or the average distance of the center-to-center distances between adjacent electrodes to each other, and d is the average thickness of the piezoelectric layer 2.

As illustrated in FIG. 6, when d/2p exceeds about 0.25, that is, d/p>about 0.5, the fractional bandwidth is less than about 5%, for example, even when d/p is adjusted. On the other hand, when d/2p about 0.25, that is, d/p about 0.5, the fractional bandwidth can be equal to or more than about 5%, for example, by changing d/p within the range, that is, the resonator having a high coupling coefficient can be formed. In addition, when d/2p is equal to or less than about 0.12, that is, d/p is equal to or less than about 0.24, the fractional bandwidth can be increased to equal to or more than about 7%, for example. In addition, when d/p is adjusted within the range, a resonator having a wider fractional bandwidth can be obtained, and a resonator having a higher coupling coefficient can be achieved. Therefore, it is understood that by setting d/p to equal to or less than about 0.5, for example, the resonator having the high coupling coefficient using the bulk waves in the above first-order thickness-shear mode can be formed.

Note that at least a pair of electrodes may be one pair of electrodes, and in the case of one pair of electrodes, p is the center-to-center distance between the adjacent electrode fingers 3 and 4 to each other. Further, in the case of 1.5 or more pairs of electrodes, the average distance of the center-to-center distances between the adjacent electrode fingers 3 and 4 to each other may be defined as p.

In addition, also for a thickness d of the piezoelectric layer 2, a value obtained by averaging the thicknesses may be used when the piezoelectric layer 2 has variations in thickness.

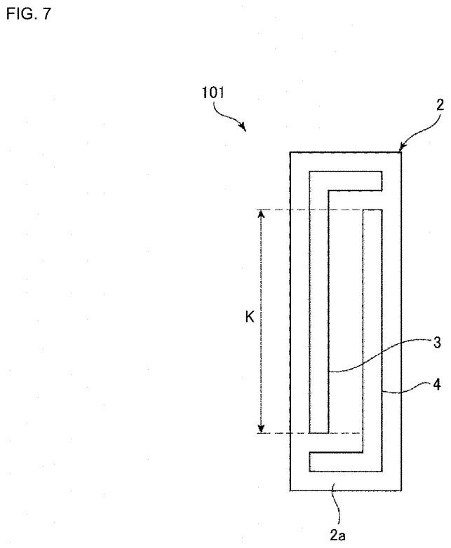

FIG. 7 is a plan view illustrating an example in which a pair of electrodes are provided in the acoustic wave device of the first preferred embodiment. In an acoustic wave device 101, a pair of electrodes including the electrode finger 3 and the electrode finger 4 are provided on the first main surface 2a of the piezoelectric layer 2. Note that K in FIG. 7 is an intersecting width. As described above, in the acoustic wave device of the present disclosure, the number of pairs of electrodes may be one. Also in this case, when the above d/p is equal to or less than about 0.5, for example, the bulk waves in the first-order thickness-shear mode can be effectively excited.

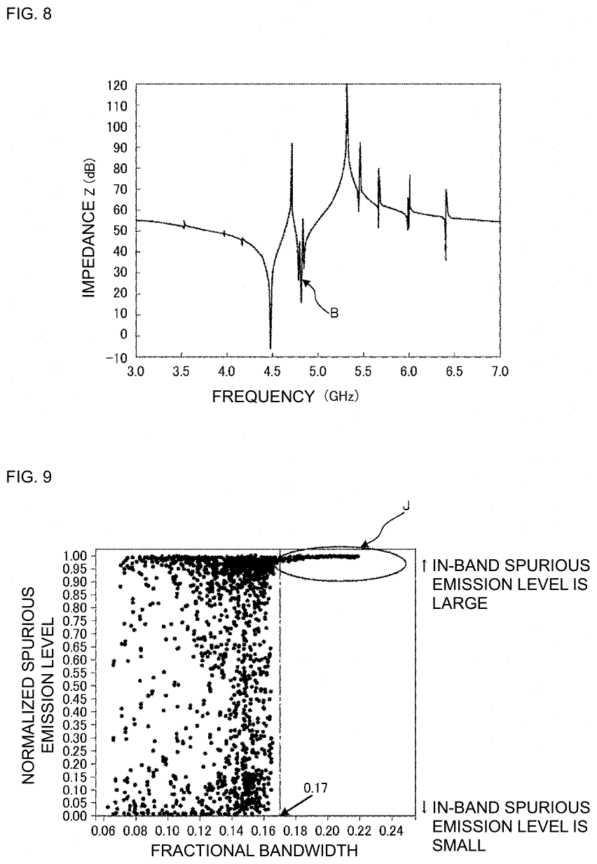

In the acoustic wave device 1, preferably, when viewed in a direction in which any adjacent electrode fingers 3 and 4 to each other of the plurality of electrode fingers 3 and 4 face each other, a metallization ratio MR of the above adjacent electrode fingers 3 and 4 to each other with respect to the excitation region C, which is a region where the adjacent electrode fingers 3 and 4 to each other overlap each other, may desirably satisfy MR≤about 1.75 (d/p)+0.075, for example. In this case, a spurious emission can be effectively reduced. This will be described with reference to FIG. 8 and FIG. 9.

FIG. 8 is a reference diagram illustrating an example of resonance characteristics of the acoustic wave device of the first preferred embodiment. A spurious emission indicated by an arrow B appears between the resonant frequency and the antiresonant frequency. Note that d/p=about 0.08 and Euler angles (0°, 0°, 90°) of LiNbO₃, for example, were set. In addition, the above metallization ratio was set as MR=about 0.35, for example.

The metallization ratio MR is explained with reference to FIG. 1B. When attention is paid to the pair of electrode fingers 3 and 4 in the structure of the electrodes illustrated in FIG. 1B, only the pair of electrode fingers 3 and 4 are provided. In this case, a portion surrounded by an alternate long and short dash line is the excitation region C. The excitation region C is a region where the electrode finger 3 overlaps the electrode finger 4, a region where the electrode finger 4 overlaps the electrode finger 3, and a region where the electrode finger 3 and the electrode finger 4 overlap each other in a region between the electrode finger 3 and the electrode finger 4 when the electrode finger 3 and the electrode finger 4 are viewed in a direction orthogonal to the length direction of the electrode finger 3 and the electrode finger 4, that is, in the facing direction. The area of the electrode fingers 3 and 4 in the excitation region C with respect to the area of the excitation region C is the metallization ratio MR. That is, the metallization ratio MR is the ratio of the area of the metallization portion with respect to the area of the excitation region C.

Note that when a plurality of pairs of electrode fingers 3 and 4 is provided, the rate of the metallization portion included in the entire excitation region C with respect to the total area of the excitation region C may be defined as MR.

FIG. 9 is an explanatory diagram illustrating a relationship between the fractional bandwidth and the phase rotation amount of the spurious emission impedance normalized by 180 degrees as the magnitude of a spurious emission when a large number of acoustic wave resonators are included in the acoustic wave device of the first preferred embodiment. Note that the fractional bandwidth was adjusted by variously changing the film thickness of the piezoelectric layer 2 and the dimension of the electrode fingers 3 and 4. In addition, although FIG. 9 shows the results obtained when the piezoelectric layer 2 made of the Z-cut LiNbO₃ is used, the same tendency is obtained when the piezoelectric layer 2 having another cut angle is used.

In a region surrounded by an ellipse J in FIG. 9, a spurious emission level is as large as about 1.0, for example. As is clear from FIG. 9, when the fractional bandwidth exceeds about 0.17, that is, when the fractional bandwidth exceeds about 17%, for example, a large spurious emission having the spurious emission level of 1 or more appears in a pass band even when the parameters defining the fractional bandwidth are changed. That is, as in the resonance characteristics illustrated in FIG. 8, a large spurious emission indicated by the arrow B appears in the band. Therefore, the fractional bandwidth is preferably equal to or less than about 17%, for example. In this case, the spurious emission can be reduced by adjusting the film thickness of the piezoelectric layer 2 and the dimension of the electrode fingers 3 and 4.

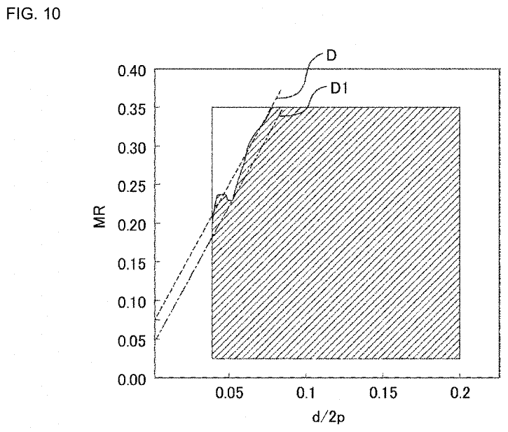

FIG. 10 is an explanatory diagram illustrating a relationship between d/2p, the metallization ratio MR, and the fractional bandwidth. In the acoustic wave device 1 of the first preferred embodiment, various acoustic wave devices 1 having different values of d/2p and different values of MR were formed, and the fractional bandwidth was measured. A hatched portion on the right side of a broken line D illustrated in FIG. 10 is a region where the fractional bandwidth is equal to or less than about 17%, for example. The boundary between the hatched region and the non-hatched region is represented by MR=about 3.5 (d/2p)+0.075. That is, MR=about 1.75 (d/p)+0.075 is satisfied, for example. Therefore, preferably, MR≤about 1.75 (d/p)+0.075 is satisfied, for example. In this case, the fractional bandwidth is easily set to be equal to or less than about 17%, for example. More preferably, it is the region in FIG. 10 on the right side of an alternate long and short dash line D1 indicating MR=about 3.5 (d/2p)+0.05, for example. That is, when MR≤about 1.75 (d/p)+0.05, the fractional bandwidth can be reliably set to equal to or less than about 17%, for example.

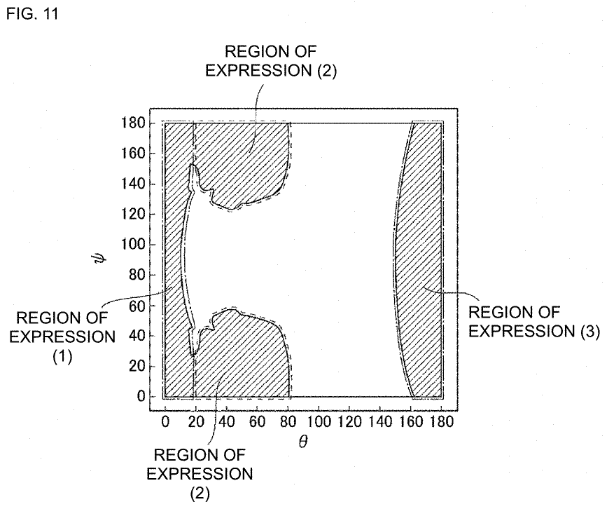

FIG. 11 is an explanatory diagram illustrating a map of the fractional bandwidth with respect to the Euler angles (0°, θ, ψ) of LiNbO₃ when d/p is made as close to 0 as possible. A hatched portion illustrated in FIG. 11 is a region where the fractional bandwidth of at least equal to or more than about 5% is obtained, for example. When the range of the region is approximated, the range is expressed by the following Expression (1), Expression (2), and Expression (3).

(0°±10°, 0° to 20°, arbitrary ψ) Expression (1)

(0°±10°, 20° to 80°, 0° to 60°(1−(θ−50)²/900)^{1/2}) or (0°±10°, 20° to 80°, [180°−60°(1−(θ−50)²/900)^{1/2}] to 180°) Expression (2)

(0°±10°, [180°−30°(1−(ψ−90)²/8100)^{1/2}] to 180°, arbitrary ψ) Expression (3)

Therefore, in the case of the Euler angle in the range of the above Expression (1), Expression (2) or Expression (3), the fractional bandwidth can be sufficiently widened, which is preferable.

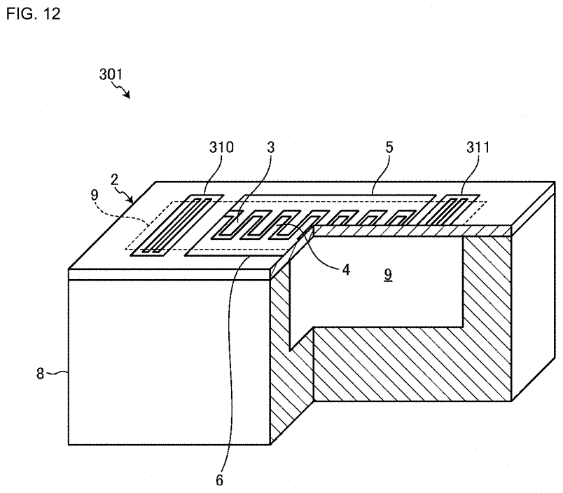

FIG. 12 is a partially cutaway perspective view for explaining an acoustic wave device according to a preferred embodiment of the present disclosure. In FIG. 12, the outer peripheral edge of the cavity portion 9 is indicated by a broken line. The acoustic wave device of the present disclosure may use plate waves. In this case, as illustrated in FIG. 12, an acoustic wave device 301 includes reflectors 310 and 311. The reflectors 310 and 311 are provided on both sides of the electrode fingers 3 and 4 of the piezoelectric layer 2 in an acoustic wave propagation direction. In the acoustic wave device 301, Lamb waves as plate waves are excited by applying an alternating electric field to the electrode fingers 3 and 4 above the cavity portion 9. Since the reflectors 310 and 311 are provided on both sides, resonance characteristics due to the Lamb waves as the plate waves can be obtained.

As described above, in the acoustic wave devices 1 and 101, the bulk waves in the first-order thickness-shear mode are used. In addition, in the acoustic wave devices 1 and 101, the first electrode finger 3 and the second electrode finger 4 are electrodes adjacent to each other, and when the thickness of the piezoelectric layer 2 is defined as d and the center-to-center distance between the first electrode finger 3 and the second electrode finger 4 is defined as p, d/p is considered to be equal to or less than about 0.5, for example. As a result, even when the acoustic wave device is reduced in size, the Q value can be increased.

In the acoustic wave devices 1 and 101, the piezoelectric layer 2 is made of lithium niobate or lithium tantalate. On the first main surface 2a or the second main surface 2b of the piezoelectric layer 2, there are the first electrode finger 3 and the second electrode finger 4 facing each other in a direction intersecting the thickness direction of the piezoelectric layer 2, and the first electrode finger 3 and the second electrode finger 4 are desirably covered with a protective film.

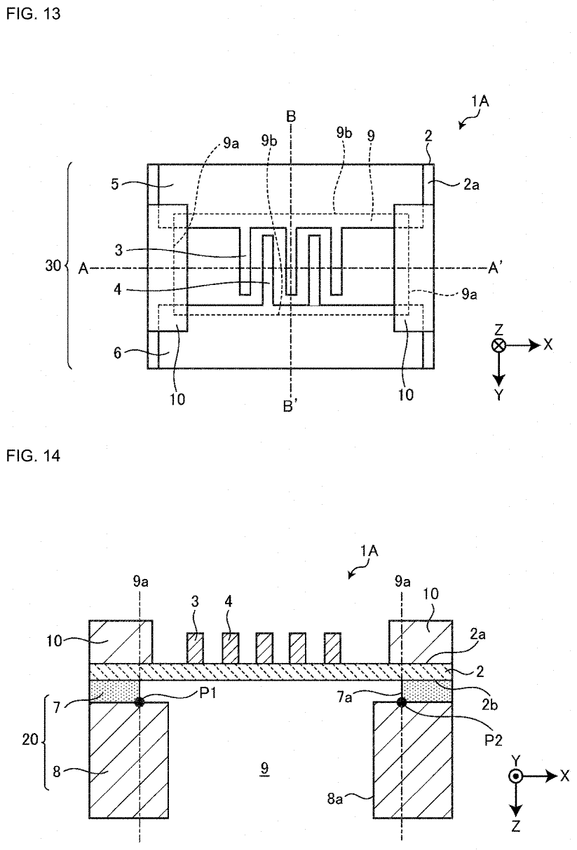

FIG. 13 is a plan view of a first example of the acoustic wave device according to the first preferred embodiment. As illustrated in FIG. 13, an acoustic wave device 1A according to the first example includes a reinforcing film 10. The reinforcing film 10 is provided so as to at least partially overlap boundaries 9a and 9b of the cavity portion 9 in a plan view in the Z direction.

FIG. 14 is a diagram illustrating an example of the cross section of a portion taken along a line A-A′ of FIG. 13. In the first preferred embodiment, the cavity portion 9 is provided in a support member 20. Here, the support member 20 is a member including the support substrate 8 and the dielectric film 7. The cavity portion 9 is provided in the support member 20 so as to open to the piezoelectric layer 2 side in the Z direction. As illustrated in FIG. 14, in the first example, the cavity portion 9 is a space surrounded by the opening portion 8a of the support substrate 8, the opening portion 7a of the dielectric film 7, and the second main surface 2b of the piezoelectric layer 2. Note that the cavity portion 9 may be provided only in the support substrate 8 or may be provided only in the dielectric film 7. In addition, in the support member 20, the dielectric film 7 is not an essential configuration, and the support member 20 may be the support substrate 8.

Here, in a plan view in the Z direction, a boundary between a region where the piezoelectric layer 2 and the cavity portion 9 overlap and a region where the piezoelectric layer 2 and the cavity portion 9 do not overlap is referred to as a “boundary of the cavity portion 9”. That is, it can be said that the boundary of the cavity portion 9 is the limit of the range in which the cavity portion 9 extends in a plan view in the Z direction. As illustrated in FIG. 13, the boundary of the cavity portion 9 includes the first boundaries 9a facing each other in the X direction and the second boundaries 9b facing each other in the Y direction. In the first example, the shape of the cavity portion 9 in a plan view in the Z direction is a rectangle. In this case, the first boundary 9a and the second boundary 9b correspond to sides of the rectangle defined by the boundaries of the cavity portion 9, the first boundary 9a is parallel to the Y direction, and the second boundary 9b is parallel to the X direction. Note that the boundary of the cavity portion 9 in a plan view in the Z direction is not limited to a rectangle. For example, in a plan view in the Z direction, the opening portion 7a may have a shape with a curved line so that the boundary of the cavity portion 9 includes the curved line.

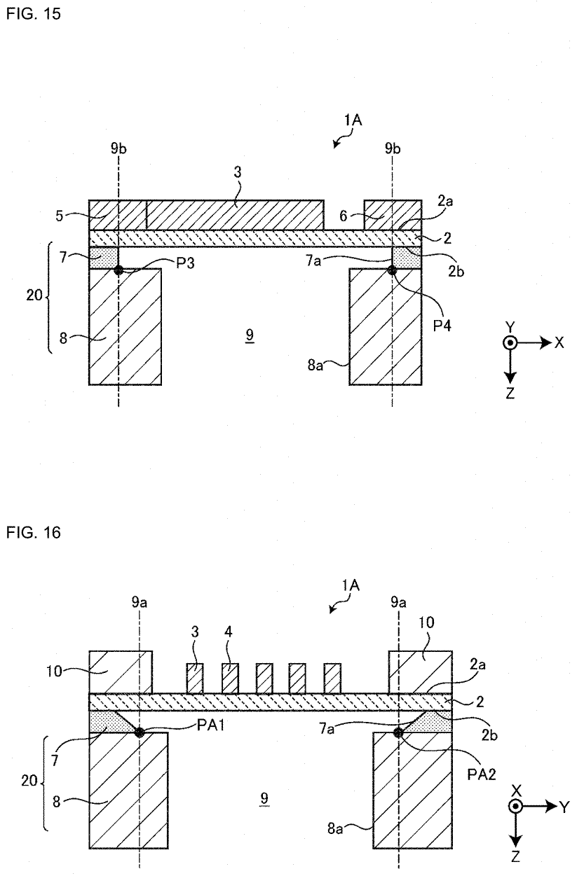

FIG. 15 is a diagram illustrating an example of the cross section of a portion taken along a line B-B′ of FIG. 13. FIG. 16 is a view illustrating another example of the cross section of a portion taken along a line A-A′ of FIG. 13. In a cross-sectional view parallel to the Z direction, the boundary of the cavity portion 9 is defined at a position overlapping a horizontally innermost point on the opening portion 7a in a plan view in the Z direction. That is, as illustrated in FIG. 14, the first boundary 9a is defined at a position overlapping an innermost point P1 or an innermost point P2 in the X direction among the points on the opening portion 7a in a plan view in the Z direction. Similarly, as illustrated in FIG. 15, the second boundary 9b is defined at a position overlapping an innermost point P3 or an innermost point P4 in the Y direction among the points on the opening portion 7a in a plan view in the Z direction. Therefore, as illustrated in FIG. 16, in the cross section taken along a line A-A′, when the opening portion 7a is formed so as to expand the opening toward the piezoelectric layer 2 side in the Z direction, the first boundary 9a is defined at a position overlapping an innermost point PA1 or an innermost point PA2 in the X direction among the points on the opening portion 7a in a plan view in the Z direction.

In the first example, the busbars 5 and 6 are provided so as to overlap the second boundary 9b in a plan view in the Z direction. In the example of FIG. 13, the busbars 5 and 6 are provided so as to overlap the second boundary 9b and the corner of the cavity portion 9 in a plan view in the Z direction. Here, the corner of the cavity portion 9 is an intersection point of the first boundary 9a and the second boundary 9b, and can also be said to be a vertex of the boundary of the cavity portion 9. Note that the busbars 5 and 6 may be provided so as to overlap a portion of the second boundary 9b in a plan view in the Z direction. Accordingly, the busbars 5 and 6 can reduce or prevent the occurrence of cracks in the piezoelectric layer 2 starting from the second boundary 9b.

The reinforcing film 10 is a film that reinforces the piezoelectric layer 2. As illustrated in FIG. 13, the reinforcing film 10 is provided on the first main surface 2a of the piezoelectric layer 2. The reinforcing film 10 is provided at a position overlapping at least a portion of the first boundary 9a or the second boundary 9b and not overlapping the excitation region C in a plan view in the Z direction. In the first example, the reinforcing film 10 is provided so as to overlap the first boundary 9a and the corner of the cavity portion 9 and so as not to overlap the electrode fingers 3 and 4 in a plan view in the Z direction. In the example of FIG. 13, two reinforcing films 10 are provided so as to be line-symmetric with respect to a line B-B′ which is the center line of the IDT electrode 30 in the X direction. By being provided at this position, it is possible to reduce or prevent the occurrence of cracks in the piezoelectric layer 2 starting from the first boundary 9a which is not covered with the busbars 5 and 6. Note that in the first example, as for the portions of the reinforcing film 10 partially overlapping the busbars 5 and 6 in a plan view in the Z direction, the busbars 5 and 6 are provided between the reinforcing film 10 and the piezoelectric layer 2, but the reinforcing film 10 may be provided between the busbars 5 and 6 and the piezoelectric layer 2.

The reinforcing film 10 has a rectangular or substantially rectangular shape in a plan view in the Z direction. In this case, in the X direction, the length of the region extending on the side of the electrode fingers 3 and 4 with the first boundary 9a as the boundary is preferably shorter than the length of the region extending on the side opposite to the electrode fingers 3 and 4. As a result, it is possible to reduce or prevent deformation of the piezoelectric layer 2 in the region overlapping the cavity portion 9 in a plan view in the Z direction and to reduce or prevent cracks in the piezoelectric layer 2 starting from the first boundary 9a. Note that the shape of the reinforcing film 10 in a plan view in the Z direction is not limited to a rectangle. In this case, in the X direction, the average of the lengths of the region extending on the side of the electrode fingers 3 and 4 is preferably shorter than the average of the lengths of the region extending on the side opposite to the electrode fingers 3 and 4 in the X direction.

The film thickness of the reinforcing film 10 is preferably equal to or greater than the film thickness of the electrode fingers 3 and 4. Here, the film thickness of the reinforcing film 10 refers to the distance from the surface in contact with the first main surface 2a to the surface on the opposite side in the Z direction to the surface in contact with the first main surface 2a. As such, it is possible to further reduce or prevent cracks in the piezoelectric layer 2 starting from the first boundary 9a. Note that when a plurality of reinforcing films 10 is provided as illustrated in FIG. 13, the plurality of reinforcing films 10 preferably has the same film thickness.

The reinforcing film 10 may be made of any material as long as it does not electrically connect the busbars 5 and 6, but is preferably made of an insulating material such as polyimide resin, silicon oxide or the like. As a result, as compared with the case where the reinforcing film 10 is made of metal, it is possible to reduce or prevent the generation of parasitic capacitance and to reduce or prevent cracks in the piezoelectric layer 2. Note that when the plurality of reinforcing films 10 is provided as illustrated in FIG. 13, they are preferably made of the same material.

Although the acoustic wave device 1A according to the first preferred embodiment has been described above, the configuration of the acoustic wave device of the first preferred embodiment is not limited thereto.

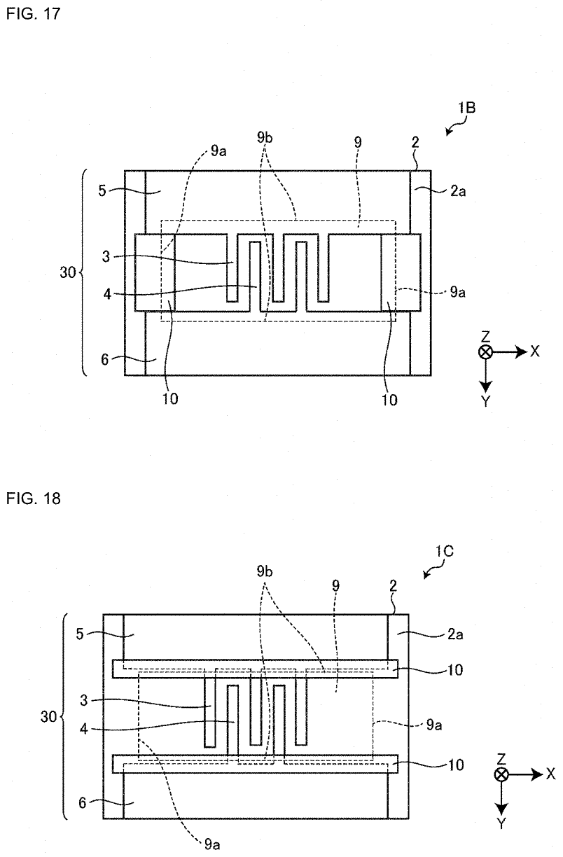

FIG. 17 is a plan view of a second example of the acoustic wave device according to the first preferred embodiment. As illustrated in FIG. 17, in an acoustic wave device 1B according to the second example, the reinforcing film 10 may be provided so as not to overlap the busbars 5 and 6 or may be provided so as to overlap only a portion of the first boundary 9a in a plan view in the Z direction. Also in this case, it is possible to reduce or prevent cracks in the piezoelectric layer 2 starting from the first boundary 9a.

In addition, the reinforcing film 10 may be provided so as to overlap the IDT electrode 30 in a plan view in the Z direction. In this case, the reinforcing film 10 is preferably provided on the main surface (for example, the second main surface 2b), of the main surfaces of the piezoelectric layer 2, opposite to the main surface (for example, the first main surface 2a) on which the IDT electrode 30 is provided. With this configuration, it is possible to reduce or prevent disconnection of the IDT electrode 30 as compared with the case where the reinforcing film 10 is provided between the IDT electrode 30 and the piezoelectric layer 2.

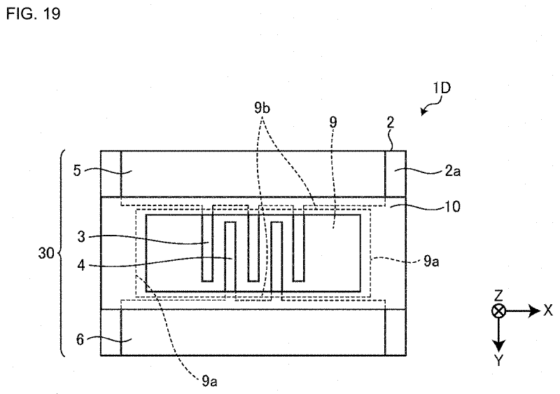

FIG. 18 is a plan view of a third example of the acoustic wave device according to the first preferred embodiment. FIG. 19 is a plan view of a fourth example of the acoustic wave device according to the first preferred embodiment. As illustrated in FIG. 18 and FIG. 19, in an acoustic wave device 1C according to the third example and an acoustic wave device 1D according to the fourth example, the busbars 5 and 6 may be provided so as not to overlap the boundaries 9a and 9b in a plan view in the Z direction. In this case, the reinforcing film 10 may be provided so as to overlap the busbars 5 and 6 in a plan view in the Z direction, but is preferably provided so as to overlap the first boundary 9a or the second boundary 9b. For example, as illustrated in FIG. 18, the reinforcing film 10 may be provided so as to overlap the second boundary 9b in a plan view in the Z direction, or as illustrated in FIG. 19, the reinforcing film 10 may be provided so as to overlap both the first boundary 9a and the second boundary 9b in a plan view in the Z direction. Note that even when the busbars 5 and 6 do not overlap the boundaries 9a and 9b, the reinforcing film 10 is not limited to being provided so as to overlap the entire second boundary 9b in a plan view in the Z direction, and may be provided so as to overlap a portion of the second boundary 9b.

As described above, the acoustic wave devices 1A to 1D according to the first preferred embodiment include the support member 20 having the support substrate 8, the piezoelectric layer 2 that includes lithium niobate or lithium tantalate and is provided in the first direction, which is the thickness direction of the support substrate 8 of the support member 20, the IDT electrode 30 provided in the first direction of the piezoelectric layer 2 and including the first busbar 5 and the second busbar 6 that face each other, the plurality of first electrode fingers 3 each including a base end connected to the first busbar 5, and the plurality of second electrode fingers 4 each including a base end connected to the second busbar 6, and the reinforcing film 10 provided in the first direction of the piezoelectric layer 2, in which the support member 20 is provided with the cavity portion 9 that is open to the piezoelectric layer 2 side in the first direction, and the reinforcing film 10 is provided so as to overlap at least a portion of the boundary (first boundary 9a or second boundary 9b) between the region where the piezoelectric layer 2 and the cavity portion 9 overlap and the region where the piezoelectric layer 2 and the cavity portion 9 do not overlap in a plan view in the first direction.

With the above-described structure, the reinforcing film 10 can protect the portion of the piezoelectric layer 2 overlapping the boundary of the cavity portion 9 in a plan view in the Z direction. As a result, the occurrence of cracks in the piezoelectric layer 2 can be reduced or prevented.

As a desirable aspect, in the acoustic wave devices 1A to 1D, when viewed in a direction in which the plurality of first electrode fingers 3 and the plurality of second electrode fingers 4 are arranged, in a case where a region (for example, the excitation region C) where the first electrode fingers 3 and the second electrode fingers 4 overlap is defined as an intersection region, the reinforcing film 10 is provided so as not to overlap the intersection region in a plan view in the first direction. As a result, the occurrence of cracks in the piezoelectric layer 2 can be reduced or prevented without disturbing the excitation of the electrode fingers 3 and 4 in the intersection region.

In addition, the first busbar 5 and the second busbar 6 are provided so as to overlap at least a portion of the boundaries 9b, among the boundaries, provided so as to face each other in the second direction which is the length direction of the first electrode finger 3 and the second electrode finger 4, and the reinforcing film 10 is provided so as to overlap at least a portion of the boundaries 9a, among the boundaries, provided so as to face each other in the third direction orthogonal to the first direction and the second direction. As a result, it is possible to reduce or prevent the occurrence of cracks in the piezoelectric layer 2 around the boundary, among the boundary of the cavity portion 9, in which the busbars 5 and 6 are not provided.

In addition, the first busbar 5 and the second busbar 6 are provided so as not to overlap the boundaries 9b, among the boundaries, provided so as to face each other in the second direction which is the length direction of the first electrode fingers 3 and the second electrode fingers 4, and the reinforcing film 10 is provided so as to overlap at least a portion of the boundaries 9b, among the boundaries, provided so as to face each other in the second direction. As a result, it is possible to reduce or prevent the occurrence of cracks in the piezoelectric layer 2 around the boundary, among the boundaries of the cavity portion 9, in which the busbars 5 and 6 are not provided.

As a desirable aspect, in a plan view in the first direction, the length of the reinforcing film 10 extending toward the first and second electrode fingers 3 and 4 side with respect to the boundary 9a is shorter than the length of the reinforcing film 10 extending toward the side opposite to the first and second electrode fingers 3 and 4 with respect to the boundary 9a. Accordingly, in the region of the piezoelectric layer 2 overlapping the cavity portion 9 in a plan view in the Z direction, it is possible to further reduce or prevent the occurrence of cracks in the piezoelectric layer 2 while reducing or preventing the deformation of the piezoelectric layer 2.

As a desirable aspect, the reinforcing film 10 includes a region overlapping the first busbar 5 or the second busbar 6 in a plan view in the first direction. As a result, the occurrence of cracks in the piezoelectric layer 2 can be reduced or prevented.

Further, in this region, the reinforcing film 10 may be provided between the first busbar 5 or the second busbar 6 and the piezoelectric layer 2. Also in this case, the occurrence of cracks in the piezoelectric layer 2 can be reduced or prevented.

In addition, in this region, the first busbar 5 or the second busbar 6 may be provided between the reinforcing film 10 and the piezoelectric layer 2. Also in this case, the occurrence of cracks in the piezoelectric layer 2 can be reduced or prevented.

As a desirable aspect, the reinforcing film 10 contains a polyimide resin. As a result, the occurrence of cracks in the piezoelectric layer 2 can be further reduced or prevented.

As a desirable aspect, the reinforcing film 10 includes silicon oxide. As a result, the occurrence of cracks in the piezoelectric layer 2 can be further reduced or prevented.

As a desirable aspect, the cavity portion 9 is a rectangle in a plan view in the first direction, and the reinforcing film 10 is provided so as to overlap a corner of the cavity portion 9 in a plan view in the first direction. As a result, the occurrence of cracks in the piezoelectric layer 2 can be further reduced or prevented.

As a more desirable aspect, the first busbar 5 or the second busbar 6 is provided so as to overlap the corner of the cavity portion 9 in a plan view in the first direction. As a result, the occurrence of cracks in the piezoelectric layer 2 can be further reduced or prevented. Thus, the occurrence of cracks in the piezoelectric layer 2 can be further reduced or prevented.

As a further desirable aspect, the Euler angles (φ, θ, ψ) of lithium niobate or lithium tantalate of the piezoelectric layer 2 are in the range of the Expression (1), Expression (2), or Expression (3). In this case, the fractional bandwidth can be sufficiently widened.

(0°±10°, 0° to 20°, arbitrary ψ) Expression (1)

(0°±10°, 20° to 80°, 0° to 60°(1−(θ−50)²/900)^{1/2}) or (0°±10°, 20° to 80°, [180°−60°(1−(θ−50)²/900)^{1/2}] to 180°) Expression (2)

(0°±10°, [180°−30°(1−(ψ−90)²/8100)^{1/2}] to 180°, arbitrary ψ) Expression (3)

As a desirable aspect, the acoustic wave device is configured such that bulk waves in the thickness-shear mode can be used. As a result, the coupling coefficient is increased so that the acoustic wave device having excellent resonance characteristics can be provided.

As a desirable aspect, when the film thickness of the piezoelectric layer 2 is defined as d and the center-to-center distance between the adjacent first and second electrode fingers 3 and 4 to each other is defined as p, d/p is equal to or less than about 0.5, for example. As a result, the acoustic wave device 1 can be reduced in size and the Q value can be increased.

As a further desirable aspect, d/p is equal to or less than about 0.24, for example. As a result, the acoustic wave device 1 can be reduced in size and the Q value can be increased.

As a desirable aspect, a region where the adjacent electrode fingers 3 and 4 to each other overlap in their facing direction is the excitation region C, and when a metallization ratio of the plurality of electrode fingers 3 and 4 with respect to the excitation region C is defined as MR, MR≤about 1.75 (d/p)+0.075 is satisfied, for example. In this case, the fractional bandwidth can be reliably set to equal to or less than about 17%, for example.

As a desirable aspect, in the configuration, plate waves can be used. As a result, the acoustic wave device having excellent resonance characteristics can be provided.

In addition, the support member 20 further includes the dielectric film 7 provided between the support substrate 8 and the piezoelectric layer 2, and the cavity portion 9 may be provided in the dielectric film 7. Also in this case, the occurrence of cracks in the piezoelectric layer 2 can be reduced or prevented.

In addition, the cavity portion 9 may be provided in the support substrate 8. Also in this case, the occurrence of cracks in the piezoelectric layer 2 can be reduced or prevented.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate;
a piezoelectric layer that includes lithium niobate or lithium tantalate and is provided in a first direction, which is a thickness direction of the support substrate;
an interdigital transducer (IDT) electrode provided in the first direction of the piezoelectric layer and including a first busbar and a second busbar that face each other, a plurality of first electrode fingers each including a base end connected to the first busbar, and a plurality of second electrode fingers each including a base end connected to the second busbar; and
a reinforcing film provided in the first direction of the piezoelectric layer; wherein
the support is provided with a cavity that is open to the piezoelectric layer side in the first direction; and
the reinforcing film overlaps at least a portion of a boundary between a region where the piezoelectric layer and the cavity overlap and a region where the piezoelectric layer and the cavity do not overlap in a plan view in the first direction.

2. The acoustic wave device according to claim 1, wherein when viewed in a direction in which a plurality of first electrode fingers and a plurality of second electrode fingers are arranged, in a case where a region where the first electrode finger and the second electrode finger overlap each other is defined as an intersection region, the reinforcing film does not overlap the intersection region in a plan view in the first direction.

3. The acoustic wave device according to claim 1, wherein
the first busbar and the second busbar overlap at least a portion of the boundaries facing each other in a second direction, which is a length direction of the first electrode finger and the second electrode finger; and
the reinforcing film overlaps at least a portion of the boundaries facing each other in a third direction orthogonal to the first direction and the second direction.

4. The acoustic wave device according to claim 1, wherein
the first busbar and the second busbar do not overlap the boundaries facing each other in a second direction, which is a length direction of the first electrode finger and the second electrode finger; and
the reinforcing film overlaps at least a portion of the boundaries facing each other in the second direction.

5. The acoustic wave device according to claim 1, wherein, in a plan view in the first direction, a length of the reinforcing film extending toward the first electrode finger and the second electrode finger side with respect to the boundary is shorter than a length of the reinforcing film extending toward a side opposite to the first electrode finger and the second electrode finger with respect to the boundary.

6. The acoustic wave device according to claim 1, wherein the reinforcing film includes a region overlapping the first busbar or the second busbar in a plan view in the first direction.

7. The acoustic wave device according to claim 6, wherein, in the region, the reinforcing film is between the first busbar or the second busbar and the piezoelectric layer.

8. The acoustic wave device according to claim 6, wherein, in the region, the first busbar or the second busbar is between the reinforcing film and the piezoelectric layer.

9. The acoustic wave device according to claim 1, wherein the reinforcing film includes a polyimide resin.

10. The acoustic wave device according to claim 1, wherein the reinforcing film includes silicon oxide.

11. The acoustic wave device according to claim 1, wherein
the cavity has a rectangular or substantially rectangular shape in a plan view in the first direction; and
the reinforcing film overlaps a corner of the cavity in a plan view in the first direction.

12. The acoustic wave device according to claim 11, wherein the first busbar or the second busbar overlap a corner of the cavity in a plan view in the first direction.

13. The acoustic wave device according to claim 1, wherein
Euler angles (φ, θ, ψ) of lithium niobate or lithium tantalate of the piezoelectric layer are within a range defined by Expression (1), Expression (2), or Expression (3):
(0°±10°, 0° to 20°, arbitrary ψ) Expression (1)
(0°±10°, 20° to 80°, 0° to 60°(1−(θ−50)²/900)^{1/2}) or (0°±10°, 20° to 80°, [180°−60°(1−(θ−50)²/900)^{1/2}] to 180°) Expression (2)
(0°±10°, [180°−30°(1−(ψ−90)²/8100)^{1/2}] to 180°, arbitrary ψ) Expression (3)

14. The acoustic wave device according to claim 13, wherein the acoustic wave device is structured to generate bulk waves in a thickness-shear mode.

15. The acoustic wave device according to claim 1, wherein when a film thickness of the piezoelectric layer is defined as d, and a center-to-center distance between the first electrode finger and the second electrode finger adjacent to each other is defined as p, a ratio d/p is equal to or less than about 0.5.

16. The acoustic wave device according to claim 15, wherein the ratio d/p is equal to or less than about 0.24.

17. The acoustic wave device according to claim 15, wherein a region where the first electrode finger and the second electrode finger adjacent to each other overlap when viewed in a direction in which the first electrode finger and the second electrode finger face each other is an excitation region, and when a metallization ratio of the plurality of first electrode fingers and the plurality of second electrode fingers with respect to the excitation region is defined as MR, MR≤about 1.75 (d/p)+0.075 is satisfied.

18. The acoustic wave device according to claim 1, wherein the acoustic wave device is structured to generate plate waves.

19. The acoustic wave device according to claim 1, wherein
the support further includes a dielectric film between the support substrate and the piezoelectric layer; and
the cavity is in the dielectric film.

20. The acoustic wave device according to claim 1, wherein
the cavity is in the support substrate.
